(19) United States
(12) Patent Application Publication
(10) Pub. No.: US 2023/0326784 A1
(43) Pub. Date: Oct. 12, 2023

(54) EXPOSURE APPARATUS AND METHOD OF MANUFACTURING DISPLAY DEVICE USING THE SAME

(71) Applicant: Samsung Display Co., LTD., Yongin-si (KR)

(72) Inventors: SEUNG-WAN KIM, Seongnam-si (KR); EUNHO JUNG, Cheonan-si (KR); JAECHEOL LEE, Cheonan-si (KR); DONGWON HAN, Seoul (KR)

(21) Appl. No.: 18/133,225

(22) Filed: Apr. 11, 2023

(30) Foreign Application Priority Data
Apr. 12, 2022 (KR) 10-2022-0045082

(51) Int. Cl. H01L 21/687; H01L 21/67

(52) U.S. Cl. CPC H01L 21/68742; H01L 21/67115

(57) ABSTRACT

An exposure apparatus includes a stage on which a target substrate is loaded and in which a plurality of holes are defined, a light source part radiating light to the stage, and a plurality of support pins disposed to penetrate the plurality of holes and supporting the target substrate, the plurality of support pins include a fixed support pin whose position is fixed in a plan view and a first variable support pin capable of reciprocating movement in a first direction, and the plurality of holes include a pair of first holes penetrated by the fixed support pin and arranged side by side at a predetermined interval along the first direction and a second hole penetrated by the first variable support pin and disposed between the pair of first holes.

This application claims priority to Korean Patent Application No. 10-2022-0045082, filed on Apr. 12, 2022, and all the benefits accruing therefrom under 35 U.S.C. § 119, the content of which in its entirety is herein incorporated by reference.

### BACKGROUND

### 1. Field

The disclosure relates to an exposure apparatus and a method of manufacturing a display device using the same.

### 2. Description of the Related Art

The display device includes a thin film encapsulation layer that blocks the inflow of moisture or oxygen in order to protect elements formed on the substrate from an external environment.

In the process of forming the thin film encapsulation layer, a process of forming an organic layer by exposing and curing a monomer layer applied on the substrate is performed.

### SUMMARY

Embodiments provide an exposure apparatus capable of improving a yield of a display device.

Embodiments provide a method for manufacturing a display device using the exposure apparatus.

An exposure apparatus according to an embodiment includes: a stage on which a target substrate is loaded and in which a plurality of holes are defined; a light source part, which radiates light to the stage; and a plurality of support pins disposed to penetrate the plurality of holes and supporting the target substrate. The plurality of support pins include: a fixed support pin whose position is fixed in a plan view; and a first variable support pin configured to reciprocate in a first direction. The plurality of holes include: a pair of first holes penetrated by the fixed support pin and arranged side by side at a predetermined interval along the first direction; and a second hole penetrated by the first variable support pin and disposed between the pair of first holes.

In an embodiment, the target substrate may include an active area in which a plurality of cells are disposed and a non-active area surrounding the active area, and the plurality of support pins may support the target substrate, and contact a lower surface of the target substrate while being spaced apart from the active area in the plan view.

In an embodiment, the plurality of support pins may support the target substrate, and contact the lower surface of the target substrate while overlapping the non-active area in the plan view.

In an embodiment, the target substrate may include a base substrate and a monomer layer disposed on the base substrate and including a monomer.

In an embodiment, the exposure apparatus may further include a support pin moving part which lifts or lowers the plurality of support pins.

In an embodiment, second hole may be provided in plural, and the plurality of second holes may extend in a second direction crossing the first direction and be arranged side by side along the first direction.

In an embodiment, a maximum value of a reciprocating movement range of the first variable support pin in the first direction may be about 400 millimeters (mm).

In an embodiment, a width of each of the second hole in the first direction may be about 800 mm.

In an embodiment, the plurality of second holes may include three or more second holes.

In an embodiment, the exposure apparatus may further include a driving part which reciprocates the first variable support pin in the first direction.

In an embodiment, the driving part may include: a ball screw rotatably coupled to a side surface of a pin frame accommodating the first variable support pin; and a motor coupled to the ball screw and which rotates the ball screw.

In an embodiment, the plurality of support pins may further include a second variable support pin capable of reciprocating movement in the second direction and the plurality of holes may further include third holes penetrated by the second variable support pin, extending in the first direction, and arranged in parallel along the second direction.

In an embodiment, opposite ends of each of the third hole may be connected to the pair of first holes, respectively.

In an embodiment, a maximum value of a reciprocating movement range of the second variable support pin in the second direction may be about 400 mm.

In an embodiment, a width of each of the third hole in the second direction may be about 800 mm.

In an embodiment, the plurality of second holes may include five or more of second holes and the third holes may include three or more third holes.

In an embodiment, the second holes may be arranged in a matrix form having a plurality of rows extending in the first direction and a plurality of columns extending in the second direction.

A method of manufacturing a display device according to an embodiment includes: reciprocating a plurality of support pins in a first direction or in a second direction crossing the first direction, loading a target substrate on a stage and supporting the target substrate with the plurality of support pins, lowering the plurality of support pins, radiating ultraviolet rays to the target substrate, supporting the target substrate by lifting the plurality of support pins, and unloading the target substrate from the stage.

In an embodiment, the target substrate may include an active area in which a plurality of cells are disposed and a non-active area surrounding the active area, and in the reciprocating of the plurality of support pins, positions of the plurality of support pins may be adjusted so as to support the target substrate while being spaced apart from the active area and overlapping the non-active area in a plan view.

In an embodiment, the method may further include applying a monomer layer on the base substrate of the target substrate before the loading the target substrate.

According to embodiments, the exposure apparatus may include the plurality of support pins, and the plurality of support pins may include the fixed support pins whose position is fixed in a plan view and the variable support pins capable of reciprocating movement. Accordingly, even when the exposure process is repeatedly performed on arbitrary target substrates having different planar areas and/or sizes of the cells, the plurality of support pins may continuously support the target substrate while being spaced apart from the active area and overlapping with the non-active area. Accordingly, it is possible to effectively prevent or reduce the stains on the display device.

In addition, as additional facilities or additional processes for preventing the stains are omitted, an efficiency of the exposure process may be improved and a manufacturing cost of the display device may be effectively reduced.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device manufactured using an exposure apparatus according to an embodiment.

FIG. 2 is a cross-sectional view taken along line I-I′ of FIG. 1.

FIG. 3 is a perspective view illustrating an exposure apparatus for manufacturing the display device of FIG. 1.

FIG. 4 is an exploded perspective view illustrating the exposure apparatus of FIG. 3.

FIG. 5 is a cross-sectional view illustrating a state in which a target substrate is supported by the exposure apparatus of FIG. 3.

FIG. 6 is a plan view illustrating an upper surface of a stage included in the exposure apparatus of FIG. 3.

FIGS. 7 to 9 are plan views illustrating a state in which a target substrate is loaded on a stage included in the exposure apparatus of FIG. 3.

FIGS. 10 to 16 are views illustrating a method of manufacturing the display device of FIG. 1.

FIG. 17 is a plan view illustrating an upper surface of a stage of an exposure apparatus according to another embodiment.

FIG. 18 is a plan view illustrating a state in which a target substrate is loaded on the stage of an exposure apparatus according to another embodiment.

FIG. 19 is a plan view illustrating an upper surface of a stage of an exposure apparatus according to still another embodiment.

### DETAILED DESCRIPTION

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

It will be understood that when an element is referred to as being “on” another element, it can be directly on the other element or intervening elements may be present therebetween. In contrast, when an element is referred to as being “directly on” another element, there are no intervening elements present.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

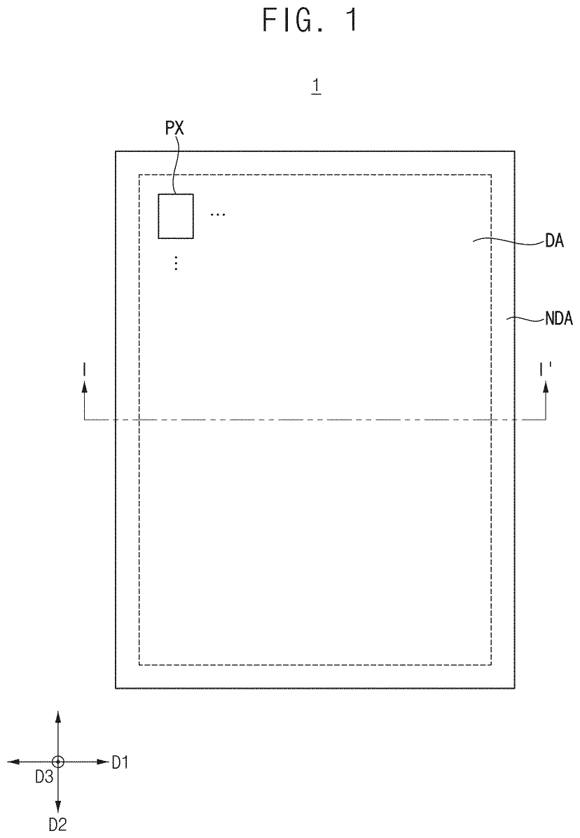

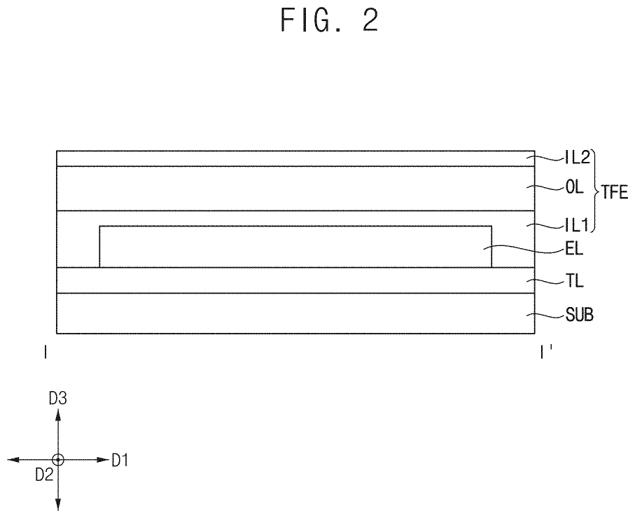

FIG. 1 is a plan view illustrating a display device manufactured using an exposure apparatus according to an embodiment, and FIG. 2 is a cross-sectional view taken along line I-I′ of FIG. 1.

Referring to FIG. 1, the display device 1 may be divided into a display area DA and a non-display area NDA. For example, the display area DA may have a rectangular shape, and the non-display area NDA may be positioned to surround the display area DA. A plurality of pixels PX may be disposed in the display area DA, and an image may be displayed through the plurality of pixels PX in the display area DA. For example, the pixels PX may be arranged in a matrix form along a first direction and a second direction crossing the first direction. Drivers for driving the pixels PX may be disposed in the non-display area NDA. The drivers may provide signals and/or voltages to the pixels PX. The pixels PX may emit light in response to the signal and/or the voltage.

Referring to FIG. 2, the display device 1 may include a substrate SUB, a transistor layer TL, a light emitting device layer EL, and a thin film encapsulation layer TFE.

The substrate SUB may include a transparent or opaque material. In an embodiment, examples of materials that can be used as the substrate SUB may include glass, quartz, plastic, or the like. These may be used alone or in combination with each other. When the substrate SUB is formed of rigid glass, the display device 1 may be implemented as a rigid display device. When the substrate SUB is formed of flexible plastic, the display device 1 may be implemented as a flexible display device.

The transistor layer TL may be disposed on the substrate SUB. The transistor layer TL may control a brightness of the pixels PX by controlling current delivered to each of the pixels PX of the display device 1. For example, the transistor layer TL may include an active layer, a gate electrode, a capacitor, and a connection electrode. The active layer may be formed of a semiconductor material, the gate electrode and the connection electrode may control current flowing through the active layer, and the capacitor may store the current.

The light emitting device layer EL may be disposed on the transistor layer TL. The light emitting device layer EL may include an anode, a cathode, and an organic emission layer. The organic emission layer may be disposed between the anode and the cathode. The organic emission layer may include an organic compound which emits light by recombination of charges and holes transferred through the anode and the cathode.

The thin film encapsulation layer TFE may be disposed on the light emitting device layer EL. The thin film encapsulation layer TFE may cover the light emitting device layer EL and prevent impurities, moisture, or the like from permeating the light emitting device layer EL from outside. The thin film encapsulation layer TFE may include at least one inorganic layer and at least one organic layer. For example, the inorganic layer may include silicon oxide, silicon nitride, silicon oxynitride, or the like, and the organic layer may include a polymer cured material such as polyacrylate. In an embodiment, the thin film encapsulation layer TFE may include a first inorganic layer IL1 disposed on the light emitting device layer EL, an organic layer OL disposed on the first inorganic layer ILL and a second inorganic layer IL2 disposed on the organic layer OL.

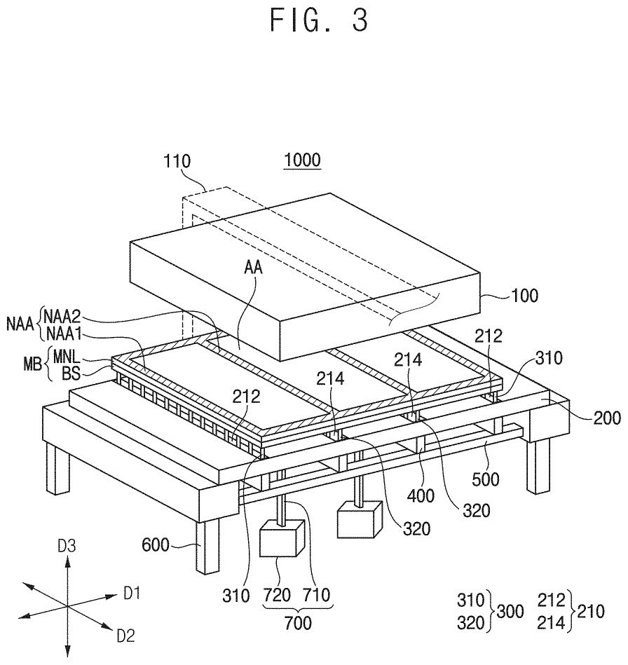

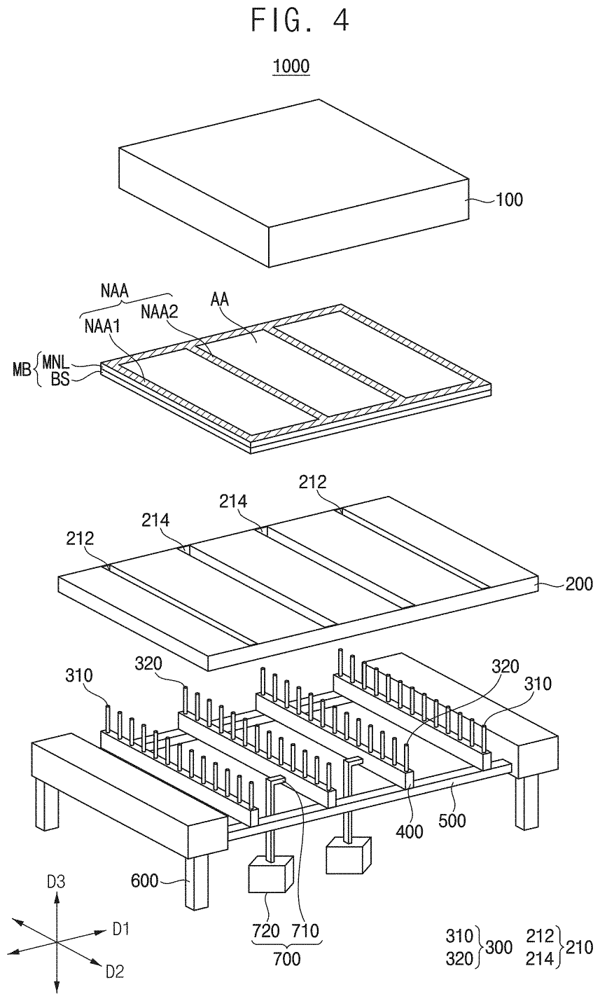

FIG. 3 is a perspective view illustrating an exposure apparatus for manufacturing the display device of FIG. 1, and FIG. 4 is an exploded perspective view illustrating the exposure apparatus of FIG. 3.

Referring to FIGS. 3 and 4, a target substrate MB may include a base substrate BS and a monomer layer MNL. The base substrate BS may include the substrate SUB, the transistor layer TL, the light emitting device layer EL, and the first inorganic layer IL1 described with reference to FIG. 2. The monomer layer MNL may be disposed on the base substrate BS. For example, the monomer layer MNL may be applied on the base substrate BS. The monomer layer MNL may include a monomer cured by exposure. Accordingly, the exposure apparatus 1000 may expose to an irradiation and cure the monomer layer MNL, and the monomer layer MNL which is cured may form the organic layer OL described with reference to FIG. 2.

In an embodiment, the target substrate MB may be divided into an active area AA and a non-active area NAA. A plurality of cells may be disposed in the active area AA. Each of the cells may correspond to one display device. That is, after the exposure process of the target substrate MB is completed, the plurality of display devices may be formed by cutting the target substrate MB into the cells. The non-active area NAA may surround the active area AA on in a plan view.

In an embodiment, the target substrate MB may include a plurality of active areas AA. The plurality of active areas AA may be spaced apart from each other in a plan view. In this case, the non-active area NAA may be divided into an outer area NAA1 and an inner area NAA2. The outer area NAA1 may be positioned at the outermost portion of the target substrate MB in a plan view and may be positioned to surround the plurality of active areas AA. The inner area NAA2 may be positioned inside the target substrate MB in a plan view and positioned between the plurality of active areas AA. In an embodiment, position of the non-active area NAA of the target substrate MB may be implemented in various ways according to a size of the cells arranged in the active area AA. Specifically, an optimized arrangement structure of the cells may be derived according to the size of the cells, and a planar area of the plurality of active areas AA may vary according to the arrangement structure. Accordingly, position of the inner area NAA2 of the non-active area NAA located between the plurality of active areas AA may be changed.

In an embodiment, the exposure apparatus 1000 may include a light source part 100, a stage 200, a plurality of support pins 300, a support pin frame 400, a support pin moving part 500, a support part 600, and a driving part 700.

The light source part 100 may emit light having a specific wavelength range. For example, the light source part 100 may emit ultraviolet rays having a wavelength range of about 10 nanometers (nm) to about 400 nm. In an embodiment, the light source part 100 may be disposed on the stage 200. For example, the light source part 100 may radiate light downward to the target substrate MB loaded on the stage 200. In an embodiment, the exposure apparatus 1000 may further include a light source moving part 110, and the light source moving part 110 may move the light source part 100 in at least one direction. In another embodiment, the light source part 100 may be fixed and the stage 200 may be moved.

The stage 200 may load the target substrate MB. In an embodiment, a plurality of holes 210 penetrated by the plurality of support pins 300 may be defined in the stage 200.

The plurality of support pins 300 may be disposed to penetrate the plurality of holes 210 of the stage 200. The plurality of support pins 300 may be lifted and lowered by the support pin moving part 500. Accordingly, the plurality of support pins 300 may be lifted to protrude from an upper surface of the stage 200 to support the target substrate MB. That is, the plurality of support pins 300 may support the target substrate MB while contacting a lower surface of the target substrate MB. Specifically, when the target substrate MB is transferred from the outside or the target substrate MB is transferred to the outside after the exposure process, the plurality of support pins 300 are lifted and lowered so as to protrude from the upper surface of the stage 200 upward and support the target substrate MB. In other words, when exposure of the target substrate MB is in progress, the plurality of support pins 300 may be lowered and may not protrude from the upper surface of the stage 200 upward. In an embodiment, as shown in FIG. 4, the plurality of support pins 300 may be arranged so that 13 support pins form one column, so as to form a total of four columns as an example. That is, the plurality of support pins 300 may be arranged so that a total of 52 support pins form a total of 4 columns. However, the present invention is not limited thereto. For another example, the number of the plurality of support pins 300 and/or the position where the plurality of support pins 300 are disposed may be variously determined according to a planar area of the target substrate MB.

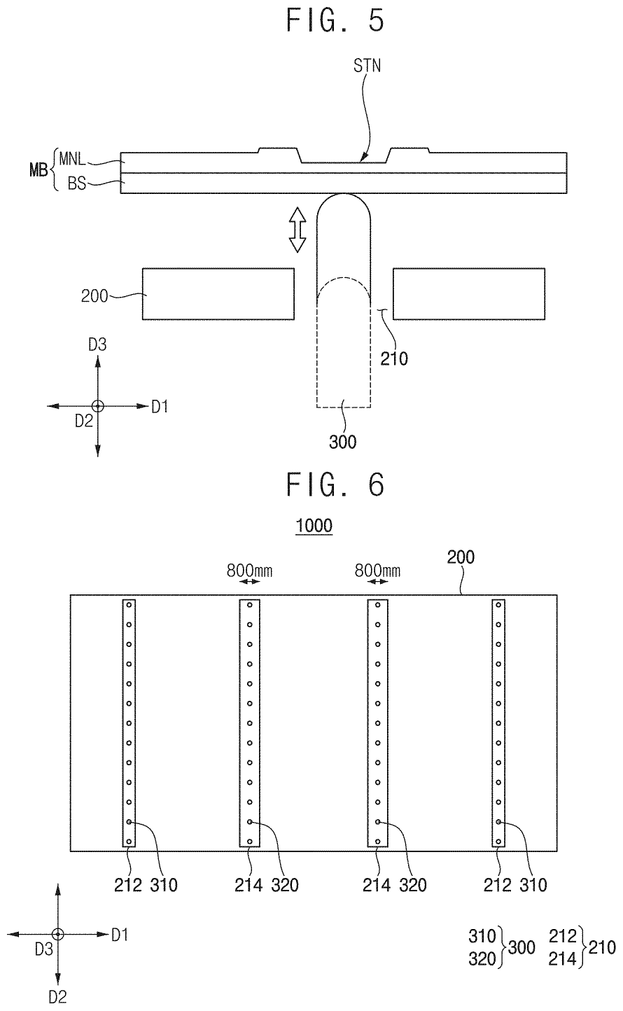

FIG. 5 is a cross-sectional view illustrating a state in which a target substrate is supported by the exposure apparatus of FIG. 3.

Referring to FIGS. 3 to 5, when the plurality of support pins 300 are lifted to protrude from the upper surface of the stage 200 upward, the plurality of support pins 300 may contact the lower surface of the target substrate MB. At this time, a temperature of the plurality of support pins 300 may be relatively high due to heat generated during exposure and curing. For example, the temperature may be higher than a temperature of an adjacent another member of exposure apparatus 1000 and/or a temperature inside a chamber in which the exposure apparatus 1000 is disposed. Accordingly, a temperature of one portion of the target substrate MB which contacts the plurality of support pins 300 may be higher than other portions of the target substrate MB which do not contact the plurality of support pins 300. For example, a temperature deviation may occur within the target substrate MB. The temperature deviation may cause a thickness deviation of the monomer layer MNL of the target substrate MB, so that stains STN may be generated. For example, a monomer included in the monomer layer MNL may be deformed due to the temperature deviation, and the spread-ability of a portion of the monomer layer MNL overlapping the plurality of support pins 300 may increase. Accordingly, the portion of the monomer layer MNL may be more recessed than other portions around the portion. That is, an edge of the portion of the monomer layer MNL may protrude. The stain STN may be visible to the naked eye, impairs aesthetics, and may cause failure or malfunction of the display device. Therefore, when supporting the target substrate 1\4B, it is desirable that the plurality of support pins 300 are disposed to be spaced apart from the active area AA of the target substrate MB and overlap the non-active area NAA of the target substrate MB in a plan view. However, as described above, the position of the non-active area NAA of the target substrate MB may vary depending on the size of the cells arranged in the active area AA. Therefore, it may be desirable to adjust the positions of the plurality of support pins 300 in order that the plurality of support pins 300 support the target substrate MB while being spaced apart from the active area AA and overlapping the NAA of the target substrate MB continuously even when the exposure process is repeatedly performed on arbitrary target substrates MB.

Referring back to FIGS. 3 and 4, the plurality of holes 210 defined in the stage 200 may include a pair of first holes 212 and second holes 214 disposed between the pair of first holes 212. Also, the plurality of support pins 300 may include fixed support pins 310 and first variable support pins 320.

The first holes 212 may be penetrated by the fixed support pins 310. In an embodiment, the first holes 212 may be arranged side by side at a predetermined interval along the first direction D1. In other words, the first holes 212 may be spaced apart from each other in the first direction D1. In an embodiment, the first holes 212 may extend in the second direction D2. For example, an extension direction of each of the first holes 212 may be parallel to an extension direction of a short side of the stage 200.

The second holes 214 may be penetrated by the first variable support pins 320. The second holes 214 may be disposed between the pair of first holes 212 arranged side by side at the predetermined interval along the first direction D1. In an embodiment, the second holes 214 may extend in the second direction D2 and may be arranged in parallel along the first direction D1. For example, an extension direction of the second holes 214 may be parallel to the extension direction of the short side of the stage 200. In an embodiment, the plurality of holes 210 may include two of the second holes 214. That is, between the pair of first holes 212, two of the second holes 214 extending in the second direction D2 may be disposed side by side along the first direction D1. However, the present invention is not limited thereto, and the number of second holes 214 may be variously changed according to the planar area of the target substrate MB and/or the size of the cells disposed on the target substrate MB. For example, the plurality of holes 210 may include three or more of the second holes 214 in another embodiment.

The fixed support pins 310 may be disposed to penetrate the first holes 212. That is, in a plan view, the fixed support pins 310 may be disposed to overlap the first holes 212. In an embodiment, the fixed support pins 310 may be arranged to form a pair of columns arranged side by side at a predetermined interval along the first direction D1. The fixed support pins 310 may be fixed in position in a plan view. That is, the fixed support pin 310 may not move in the first direction D1 and the second direction D2, but reciprocate only in the third direction D3 by the support pin moving part 500.

The fixed support pins 310 may support the target substrate MB while overlapping the outer area NAA1 of the non-active area NAA of the target substrate MB. Specifically, the fixed support pins 310 may support the target substrate MB while overlapping a portion extending parallel to the short side of the target substrate MB in the outer area NAA1 of the inactive area NAA. Therefore, even when the exposure process is repeatedly performed on arbitrary target substrates MB, the fixed support pins 310 may support the target substrate MB while being continuously spaced apart from the active area AA and overlapping the non-active area NAA without moving in a plan view.

The first variable support pins 320 may be disposed to penetrate the second hole 214. That is, the first variable support pins 320 may be disposed to overlap the second holes 214. The first variable support pins 320 may be arranged to form a plurality of columns between the pair of columns formed by the fixed support pins 310. For example, the first variable support pins 320 may be arranged to form two columns between the pair of columns formed by the fixed support pins 310. However, the present invention is not limited thereto, and the number of columns formed by the first variable support pins 320 variously determined according to the planar area of the target substrate MB and the number of second holes 214 defined in the stage 200. The first variable support pins 320 may reciprocate in the first direction D1. For example, the first variable support pins 320 may reciprocate in the first direction D1 by the driving part 700.

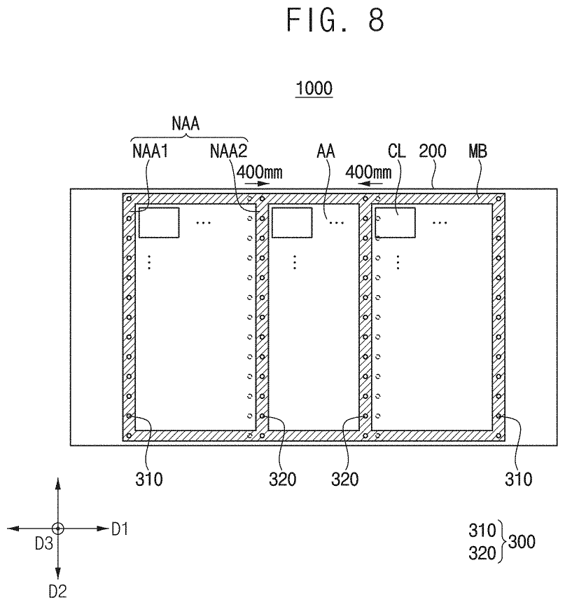

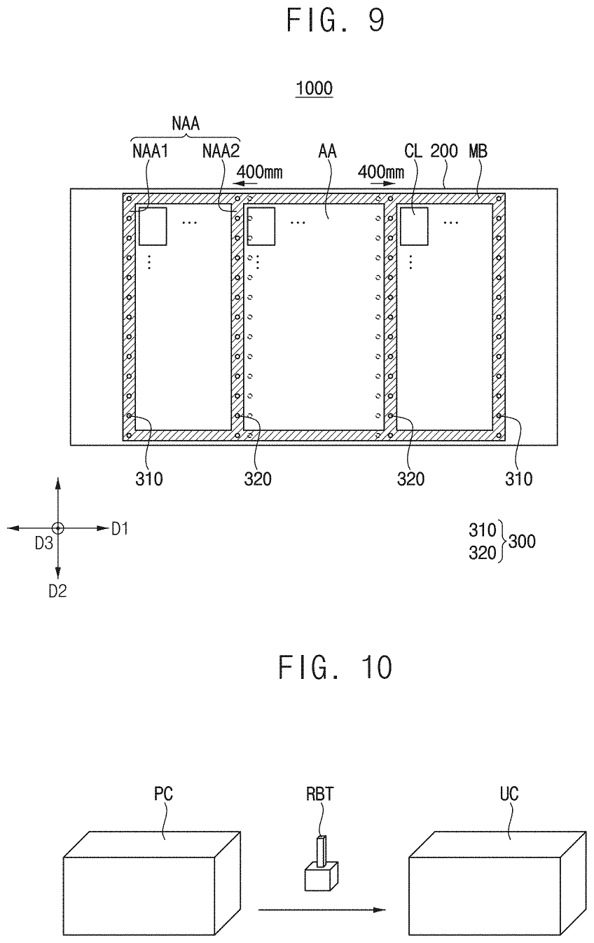

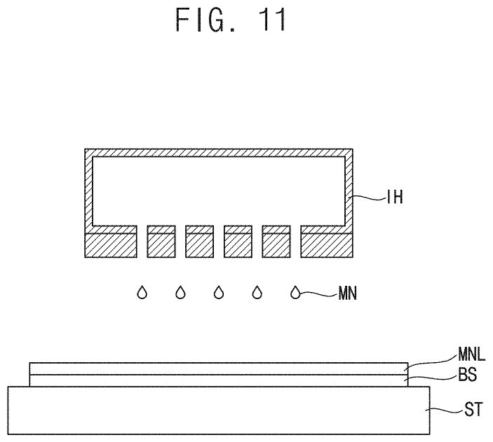

The first variable support pins 320 may support the target substrate MB while overlapping the inner area NAA2 of the non-active region NAA of the target substrate MB. As described above, when the size of the cells disposed in the active area AA is changed, the position of the inner area NAA2 in the non-active area NAA may be changed. In this case, the first variable support pins 320 may reciprocate in the first direction D1 in response to the positional change of the inner area NAA2. In other words, when the position of the inner area NAA2 is changed, the first variable support pins 320 may reciprocate along the first direction D1 to overlap the inner area NAA2 in a plan view. Therefore, even when the exposure process is repeatedly performed on arbitrary target substrates MB having different planar areas and/or sizes of the cells, the first variable support pins 320 may support the target substrate MB while continuously being spaced apart from the active area AA and overlapping with the non-active area NAA of the target substrate MB through a reciprocating movement in the first direction D1. This will be described later in more detail with reference to FIGS. 6 to 9.

The support pin frame 400 may accommodate the plurality of support pins 300. In an embodiment, the support pins forming one column among the plurality of support pins 300 may be integrally accommodated in one of the support pin frame 400. In this case, the support pin frame 400 may be disposed under the stage 200 by the number of columns formed by the plurality of support pins 300. However, the present invention is not limited thereto. For example, each of the plurality of support pins 300 may be individually accommodated in one of the support pin frame 400. In this case, the support pin frame 400 may be disposed under the stage 200 by the total number of the plurality of support pins 300.

The support pin moving part 500 may lift and lower the plurality of support pins 300. In an embodiment, the support pin moving part 500 may be disposed under the stage 200 and may be consisted of members of a rod shape which connects and supports a portion of the plurality of support pins 300 disposed in the second direction D2. However, the present invention is not limited thereto. In an embodiment, the support pin moving part 500 may be implemented as a cylinder driven by hydraulic pressure or pneumatic pressure. In this case, the support pin moving part 500 may further include an electromagnet. The electromagnet may fix the position of the plurality of support pins 300 after the plurality of support pins 300 are lifted and lowered by the cylinder. In another embodiment, the support pin moving part 500 may be implemented as a linear movement guide driven by a servo motor.

The support part 600 may support the stage 200. In an embodiment, the support part 600 may support opposite sides of the stage 200 extending in the first direction D1 at a predetermined height. However, the present invention is not limited thereto.

The driving part 700 may reciprocate the first variable support pins 320 in the first direction D1. In an embodiment, the driving part 700 may include a ball screw 710 and a motor 720. In an embodiment, one side of the ball screw 710 may be coupled to a side surface of the support pin frame 400 accommodating the first variable support pins 320, and the other side may be coupled to the motor 720. The motor 720 may rotate the ball screw 710. When the ball screw 710 is rotated by the motor 720, the support pin frame 400 coupled to the ball screw 710 may reciprocate in the first direction D1. That is, the support pin frame 400 coupled to the ball screw 710 may linearly move reciprocally in the first direction D1 by the rotational motion of the ball screw 710. Accordingly, the first variable support pins 320 accommodated in the support pin frame 400 coupled to the ball screw 710 may reciprocate in the first direction D1. In an embodiment, the motor 720 may be a servo motor. However, the present invention is not necessarily limited thereto. For example, the motor 720 may be composed of various types of power sources other than the servo motor.

In an embodiment, when the plurality of first variable support pins 320 forming one column are integrally accommodated in one of the support pin frame 400, the plurality of first variable support pins 320 forming one column may collectively reciprocate along the first direction D1 by operation of the driving part 700. However, the present invention is not limited thereto. For example, when each of the plurality of first variable support pins 320 is individually accommodated in one of the support pin frame 400, each of the first variable support pins 320 may individually reciprocate along the first direction D1 by the operation of the driving part 700. In an embodiment, the driving part 700 may be positioned inside an exposure chamber in which the exposure apparatus 1000 is disposed.

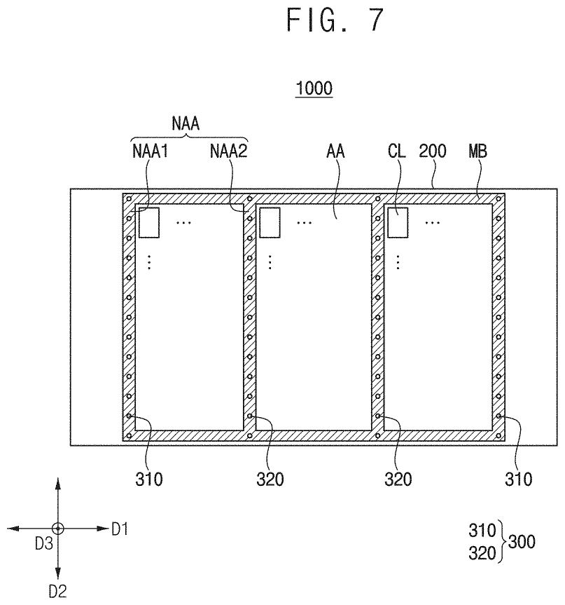

FIG. 6 is a plan view illustrating an upper surface of a stage included in the exposure apparatus of FIG. 3, and FIGS. 7 to 9 are plan views illustrating a state in which a target substrate is loaded on a stage included in the exposure apparatus of FIG. 3.

In FIGS. 6 to 9, although it is illustrated that the fixed support pins 310 are arranged to form a pair of columns, and the first variable support pins 320 are arranged to form two columns between the pair of columns formed by the fixed support pins 310, this is only an example, and the present invention is not limited thereto. In addition, in FIGS. 7 to 9, although it is illustrated that the target substrate MB is divided into three of the active areas AA and the non-active area NAA surrounds them, and accordingly, the non-active area NAA includes the outer area NAA1 and two inner areas NAA2, this is only an example, and the present invention is not limited thereto. Hereinafter, the reciprocating movement of the first variable support pins 320 in the first direction D1 will be described in more detail with reference to FIGS. 6 to 9.

As shown in FIG. 6, the plurality of holes 210 may be defined in the stage 200, and the plurality of holes 210 may include the pair of first holes 212 and the second holes 214 disposed between the pair of first holes 212. In addition, the fixed support pins 310 may be disposed to overlap the first holes 212 so as to penetrate the first holes 212, and the first variable support pins 320 may be disposed to overlap the second holes to penetrate the second hole 214.

In this case, the second holes 214 may have a sufficient space to be penetrated by the first variable support pins 320 even after the first variable support pins 320 reciprocate in the first direction D1. That is, a width of the second holes 214 in the first direction D1 may be set according to a maximum value of the reciprocating movement range of the first variable support pins 320 in the first direction D1. Accordingly, the first variable support pins 320 may freely reciprocate in the first direction D1 within the area overlapping the second holes 214. In an embodiment, the maximum value of the reciprocating movement range of the first variable support pins 320 in the first direction D1 may be about 400 millimeters (mm). In this case, the width of the second holes 214 in the first direction D1 may be about 800 mm. However, the present invention is not limited thereto, and the reciprocating movement range of the first variable support pins 320 in the first direction D1 and the width of the second holes 214 in the first direction D1 may be variously changed or determined according to the planar area of the target substrate MB and/or the size of the cells CL disposed on the target substrate MB. For example, when the reciprocating movement range of the first variable support pins 320 in the first direction D1 exceeds 400 mm, the width of the second hole 214 in the first direction D1 may also exceed 800 mm.

Referring to FIGS. 7 to 9, when the target substrate MB is loaded on the stage 200, the plurality of support pins 300 may support the target substrate MB while being spaced apart from the active area AA and overlapping with the non-active area NAA. However, when the size of the cells CL arranged in the active area AA is changed, the position of the non-active area NAA may be changed. Specifically, the position of the inner area NAA2 of the non-active area NAA positioned between the active areas AA may be changed. In response to the positional change of the inner area NAA2, the first variable support pins 320 may reciprocate in the first direction D1. That is, position of the first variable support pins 320 may be adjusted to support the target substrate MB while being spaced apart from the active area AA and overlapping with the non-active area NAA in a plan view.

In an embodiment, as the size of the cell CL is changed, one of the two inner areas NAA2 may move to right by about 400 mm in a plan view, and the other one may move to left by about 400 mm in a plan view. Correspondingly, one of the two columns formed by the first variable support pins 320 may move to the right by about 400 mm in a plan view, and the other one may move to the left by about 400 mm in a plan view. However, the present invention is not limited thereto, and the reciprocating movement range of the first variable support pins 320 in the first direction D1 corresponding to the change in the position of the inner area NAA2 may be variously changed or determined according to the planar area of the target substrate MB and/or the size of the cell CL disposed on the target substrate MB.

According to embodiments, the exposure apparatus 1000 may include the plurality of support pins 300, and the plurality of support pins 300 may include the fixed support pins 310 whose position is fixed in a plan view and the first variable support pins 320 capable of reciprocating movement in the first direction D1. Accordingly, even when the exposure process is repeatedly performed on arbitrary target substrates MB having different planar areas and/or sizes of the cells, the plurality of support pins 300 may continuously support the target substrate MB while being spaced apart from the active area AA and overlapping with the non-active area NAA. Accordingly, it is possible to prevent or reduce the stains STN on the display device. In addition, as additional facilities or additional processes for preventing the stains STN are omitted, an efficiency of the exposure process may be improved and a manufacturing cost of the display device may be reduced.

FIGS. 10 to 16 are views illustrating a method of manufacturing the display device of FIG. 1.

Referring to FIG. 10, a method of manufacturing the display device 1 may be performed using an applying chamber PC, an exposure chamber UC, and a transfer robot RBT. In an embodiment, the applying chamber PC and the exposure chamber UC may be disposed with a passage through which the transfer robot RBT moves. An applying device may be disposed in the applying chamber PC, and the exposure apparatus 1000 described with reference to FIGS. 3 to 9 may be disposed in the exposure chamber UC.

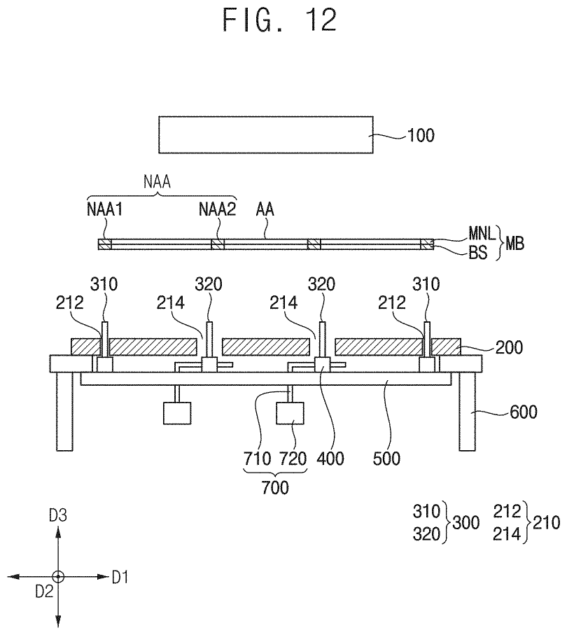

Referring to FIG. 11, the applying device may apply the monomer layer MNL on the base substrate BS of the target substrate MB. In an embodiment, the applying device may be an inkjet printing device. For example, the applying device may include a printing stage ST and an inkjet head IH. The printing stage ST may support the base substrate BS. The inkjet head IH may print the monomer layer MNL by discharging a monomer MN on the base substrate BS. However, the present invention is not limited thereto.

Referring FIG. 10 again, the transfer robot RBT may transfer the target substrate MB. The transfer robot RBT may receive the target substrate MB on which the monomer layer MNL is applied on the base substrate BS from the applying chamber PC and transfer the target substrate to the exposure chamber UC. Also, when the exposure process is completed, the transfer robot RBT may carry the target substrate MB out of the exposure chamber UC. That is, the target substrate MB may be loaded onto or unloaded from the stage 200 of the exposure apparatus 1000 by the transfer robot RBT.

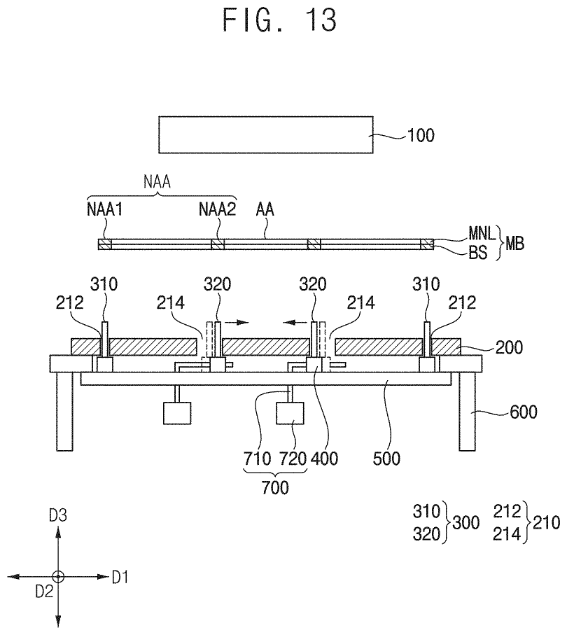

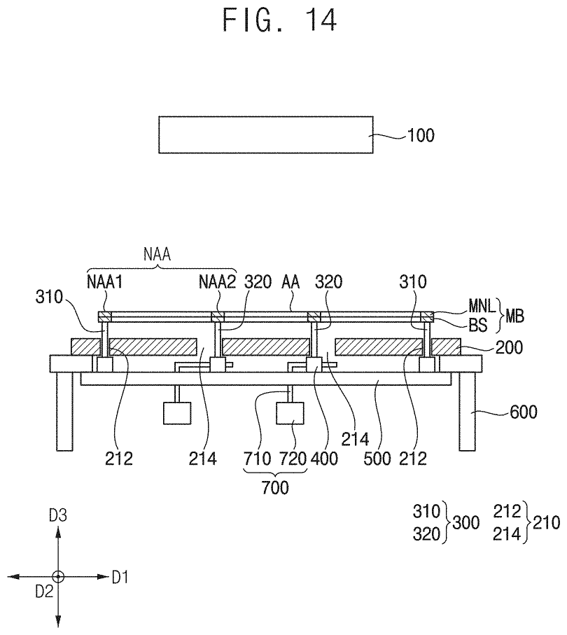

Referring to FIGS. 12 and 13, before the target substrate MB is loaded on the stage 200, the plurality of support pins 300 may be reciprocally moved in the first direction D1. Specifically, the first variable support pins 320 among the plurality of support pins 300 may be reciprocally moved in the first direction D1. In an embodiment, the reciprocating movement of the first variable support pins 320 in the first direction D1 may be performed through the driving part 700. For example, when the ball screw 710 is rotated by the motor 720, the support pin frame 400 in which the first variable support pins 320 are accommodated may reciprocate in the first direction D1 by coupling to the ball screw 710. That is, the support pin frame 400 in which the first variable support pins 320 are accommodated may reciprocate in the first direction D1 by the rotational motion of the ball screw 710. Accordingly, the first variable support pins 320 may be reciprocally moved in the first direction D1. Therefore, position of the first variable support pins 320 may be adjusted to support the target substrate MB while being spaced apart from the active area AA and overlapping with the non-active area NAA.

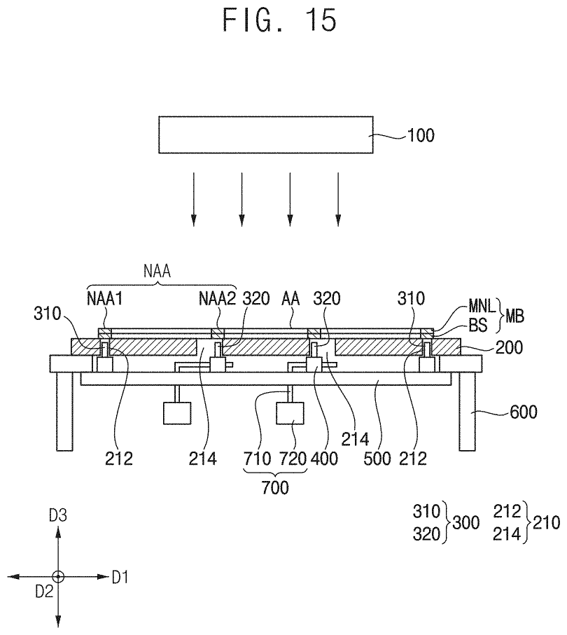

Referring to FIG. 14, the target substrate MB may be transferred from the outside and loaded onto the stage 200. In an embodiment, the target substrate MB may be transferred onto the stage 200 by the transfer robot RBT of FIG. 11. At this time, the lower surface of the target substrate MB may be supported by the plurality of support pins 300 protruding from the upper surface of the stage 200 upward and may be spaced apart from the upper surface of the stage 200. That is, the plurality of support pins 300 may support the target substrate MB and level the target substrate MB to be flatly disposed. At this time, according to the above-described position adjustment of the first variable support pins 320, the plurality of support pins 300 may continuously support the target substrate MB while being spaced apart from the active areas AA and overlapping with the non-active area NAA for arbitrary target substrates MB having different positions of the non-active area NAA. Specifically, among the plurality of support pins 300, the fixed support pins 310 may overlap the outer area NAA1 of the non-active area NAA, and the first variable support pins 320 may overlap the inner area NAA2 of the non-active area NAA.

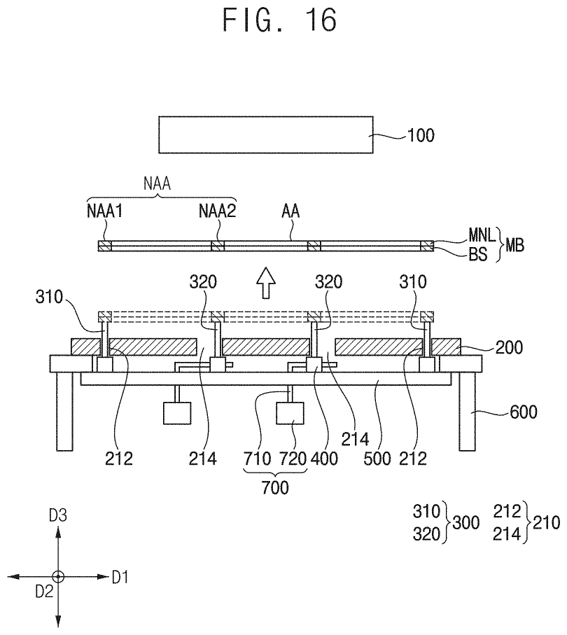

Referring to FIG. 15, the plurality of support pins 300 may be lowered, and ends of the plurality of support pins 300 may be accommodated in the plurality of holes 210 of the stage 200. In this case, the target substrate MB may be supported by the stage 200. Then, the light source part 100 may irradiate the target substrate MB with ultraviolet rays. The monomer layer MNL of the target substrate MB may be exposed to an irradiation and cured by the ultraviolet rays.

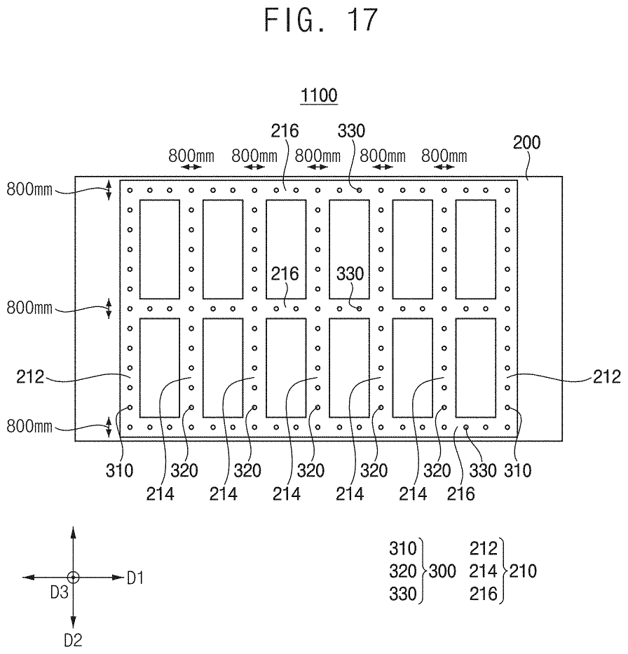

Referring to FIG. 16, after the exposure is completed, the light source part 100 may stop radiating the ultraviolet rays, and the plurality of support pins 300 may be lifted again to support the lower surface of the target substrate MB. Similarly in this case, the plurality of support pins 300 may support the target substrate MB while being spaced apart from the active area AA and overlapping with the non-active area NAA of the target substrate MB. The target substrate MB supported by the plurality of support pins 300 may be unloaded from the stage 200. For example, the target substrate MB may be carried out of the exposure chamber UC by the transfer robot RBT of FIG. 11.

According to embodiments, even when an exposure process is repeatedly performed on arbitrary target substrates MB having different planar areas and/or sizes of the cells to be disposed, the plurality of support pins 300 may continuously support the target substrate MB while being spaced apart from the active areas AA and overlapping with the non-active area NAA for arbitrary target substrates MB having different positions of the non-active area NAA. Accordingly, the stains on the display device may be prevented or reduced. In addition, as additional facilities or additional processes for preventing the stains STN are omitted, an efficiency of the exposure process may be improved and a manufacturing cost of the display device may be reduced.

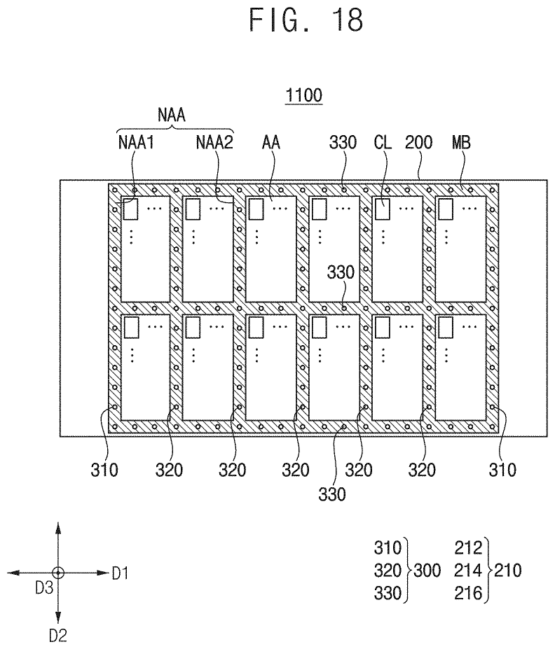

FIG. 17 is a plan view illustrating an upper surface of a stage of an exposure apparatus according to another embodiment, and FIG. 18 is a plan view illustrating a state in which a target substrate is loaded on the stage of an exposure apparatus according to another embodiment.

Referring to FIGS. 17 and 18, the exposure apparatus 1100 according to another embodiment may be substantially same as the exposure apparatus 1000 described above with reference to FIGS. 3 to 9, except for including the third holes 216 and the second variable support pins 330. Accordingly, repeated descriptions will be omitted or simplified.

In an embodiment, the plurality of holes 210 defined in the stage 200 of the exposure apparatus 1100 may further include the third holes 216. In addition, the plurality of support pins 300 may further include the second variable support pins 330.

The second holes 214 may be penetrated by the first variable support pins 320. The second holes 214 may be disposed between the pair of first holes 212 arranged side by side at the predetermined interval along the first direction D1. In an embodiment, the second holes 214 may extend in the second direction D2 and may be arranged in parallel along the first direction D1. For example, an extension direction of the second holes 214 may be parallel to the extension direction of the short side of the stage 200. In an embodiment, the plurality of holes 210 may include two of the second holes 214. That is, between the pair of first holes 212, two of the second holes 214 extending in the second direction D2 may be disposed side by side along the first direction D1. However, the present invention is not limited thereto, and the number of second holes 214 may vary depending on the planar area of the target substrate MB and/or the size of the cells disposed on the target substrate MB. For example, the plurality of holes 210 may include three or more of the second holes 214.

The third holes 216 may be penetrated by the second variable support pins 330. In an embodiment, the third holes 216 may extend in the first direction D1 and may be arranged in parallel along the second direction D2. For example, an extension direction of the third holes 216 may be parallel to an extension direction of a long side of the stage 200. Accordingly, the third holes 216 may have a lattice shape in a plan view with the second holes 214. In an embodiment, opposite ends of the third holes 216 may connected to the pair of first holes 212, be respectively, disposed side by side at the predetermined interval along the first direction D1. In an embodiment, the plurality of holes 210 may include three of the third holes 216. In this case, the plurality of holes 210 may include five of the second holes 214. However, the present invention is not limited thereto, and the number of the third holes and the number of the second holes 214 may be variously changed or determined according to the planar area of the target substrate MB and/or the size of the cells disposed on the target substrate MB. For example, the plurality of holes 210 may include three or more of the third holes 216 and five or more of the second holes 214.

The second variable support pins 330 may be disposed to penetrate the third holes 216. That is, the second variable support pins 330 may be disposed to overlap the third holes 216. The second variable support pins 330 may reciprocate in the second direction D2. For example, the second variable support pins 330 may reciprocate in the second direction D2 by the operation of the driving part. The second variable support pins 330 may be arranged to form a plurality of rows between the pair of columns formed by the fixed support pins 310. For example, the second variable support pins 330 may be arranged to form three rows between the pair of columns formed by the fixed support pins 310. However, the present invention is not limited thereto, and the number of rows formed by the second variable support pins 330 may be variously changed or determined according to the planar area of the target substrate MB and the number of the third holes 216 defined in the stage 200.

In an embodiment, the third holes 216 may have a sufficient space to be penetrated by the second variable support pins 330 even after the second variable support pins 330 reciprocate in the second direction D2. That is, a width of the third holes 216 in the second direction D2 may be set according to a maximum value of a reciprocating movement range of the second variable support pins 330 in the second direction D2. Accordingly, the second variable support pins 330 may freely reciprocate in the second direction D2 within an area overlapping the third holes 216. In one embodiment, the maximum value of the reciprocating movement range of the second variable support pins 330 in the second direction D2 may be about 400 mm. In this case, the width of the third holes 216 in the second direction D2 may be about 800 mm. However, the present invention is not limited thereto, and the reciprocating movement range of the second variable support pins 330 in the second direction D2 and the width of the third holes 216 in the second direction D2 may be variously changed or determined according to the planar area of the target substrate MB and/or the size of the cells CL disposed on the target substrate MB. For example, when the reciprocating movement range of the second variable support pins 330 in the second direction D2 exceeds 400 mm, the width of the third holes 216 in the second direction D2 may also exceed 800 mm.

As the exposure apparatus 1100 includes both the first variable support pins 320 and the second variable support pins 330, the target substrate MB may be more firmly supported by the plurality of support pins 300. Accordingly, leveling of the target substrate MB may be further improved, and when the target substrate MB is supported by the plurality of support pins 300, a phenomenon in which a center portion of the target substrate MB sags downward may be minimized. Accordingly, damage to the target substrate MB may be further reduced or prevented.

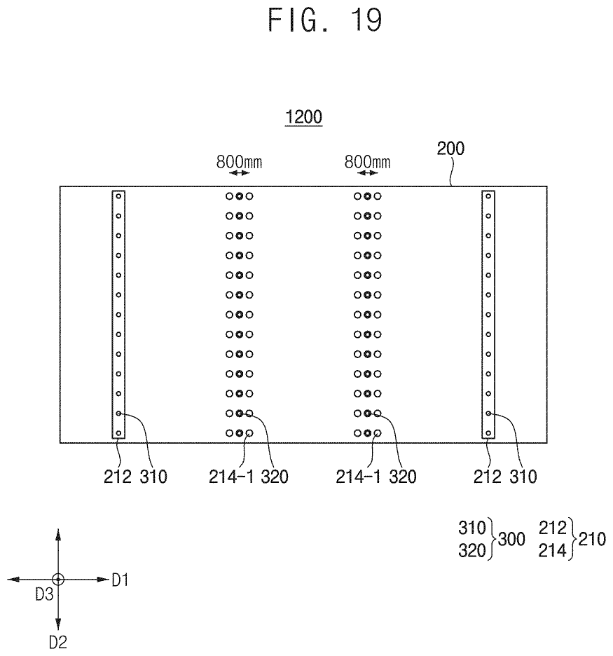

FIG. 19 is a plan view illustrating an upper surface of a stage of an exposure apparatus according to still another embodiment.

Referring to FIG. 19, the exposure apparatus 1200 according to still another embodiment may be substantially same as the exposure apparatus 1000 described above with reference to FIGS. 3 to 9, except for an arrangement of the second holes 214-1 defined in the stage 200. Accordingly, repeated descriptions will be omitted or simplified.

In an embodiment, the second holes 214-1 may be arranged in a matrix form having a plurality of rows extending in the first direction D1 and a plurality of columns extending in the second direction D2. Specifically, the second holes 214-1 may be arranged in a matrix form within a reciprocating movement range of the first variable support pins 320 in the first direction D1. In this case, since the first variable support pins 320 need to penetrate the second holes 214-1, the first variable support pins 320 may move only to positions overlapping with the second holes 214-1 arranged in a matrix form in a plan view. For example, as the first variable support pins 320 constituting one column may reciprocate in the first direction D1 by a manual operation of an operator, the first variable support pins 320 may be disposed to overlap the second holes 214-1 arranged in a matrix form in a plan view.

In an embodiment, the first variable support pins 320 may be arranged to form two columns between a pair of columns formed by the fixed support pins 310. In addition, the reciprocating movement range of the first variable support pins 320 forming any one of the two columns in the first direction D1 may be about 400 mm. In this case, the second holes 214-1 may be arranged in a matrix shape having 13 rows and 3 columns within the reciprocating movement is range of the first variable support pin 320 in the first direction D1. However, the present invention is not limited thereto, and the reciprocating movement range of the first variable support pins 320 in the first direction D1 and the number of rows and columns of the matrix form in which the second holes 214-1 are disposed may be variously changed or determined according to the planar area of the target substrate MB and/or the size of the cells CL disposed on the target substrate MB.

According to embodiments, the exposure apparatus may include the plurality of support pins 300, and the plurality of support pins 300 may include the fixed support pins whose position is fixed in a plan view and the variable support pins capable of reciprocating movement. Accordingly, even when the exposure process is repeatedly performed on arbitrary target substrates MB having different planar areas and/or sizes of the cells, the plurality of support pins 300 may continuously support the target substrate MB while being spaced apart from the active area AA and overlapping with the non-active area NAA. Accordingly, it is possible to prevent or reduce the stains on the display device. In addition, as additional facilities or additional processes for preventing the stains are omitted, an efficiency of the exposure process may be improved and a manufacturing cost of the display device may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An exposure apparatus comprising:
a stage on which a target substrate is loaded and in which a plurality of holes are defined;
a light source part, which radiates light to the stage; and
a plurality of support pins disposed to penetrate the plurality of holes and supporting the target substrate,
wherein the plurality of support pins include:
a fixed support pin whose position is fixed in a plan view; and
a first variable support pin configured to reciprocate in a first direction, and
wherein the plurality of holes include:
a pair of first holes penetrated by the fixed support pin and arranged side by side at a predetermined interval along the first direction; and
a second hole penetrated by the first variable support pin and disposed between the pair of first holes.

2. The exposure apparatus of claim 1, wherein the target substrate includes an active area in which a plurality of cells are disposed and a non-active area surrounding the active area, and
wherein the plurality of support pins are configured to support the target substrate, and contact a lower surface of the target substrate while being spaced apart from the active area in the plan view.

3. The exposure apparatus of claim 2, wherein the plurality of support pins are configured to support the target substrate, and contact the lower surface of the target substrate while overlapping the non-active area in the plan view.

4. The exposure apparatus of claim 3, wherein the target substrate includes:
a base substrate; and
a monomer layer disposed on the base substrate and including a monomer.

5. The exposure apparatus of claim 1, further comprising:
a support pin moving part, which lifts or lowers the plurality of support pins.

6. The exposure apparatus of claim 1, wherein the second hole is provided in plural, and
wherein the plurality of second holes extend in a second direction crossing the first direction and are arranged side by side along the first direction.

7. The exposure apparatus of claim 6, wherein a maximum value of a reciprocating movement range of the first variable support pin in the first direction is about 400 millimeters (mm).

8. The exposure apparatus of claim 7, wherein a width of each of the second holes in the first direction is about 800 mm.

9. The exposure apparatus of claim 8, wherein the plurality of second holes include three or more second holes.

10. The exposure apparatus of claim 6, further comprising:
a driving part, which reciprocates the first variable support pin in the first direction.

11. The exposure apparatus of claim 10, wherein the driving part includes:
a ball screw rotatably coupled to a side surface of a pin frame accommodating the first variable support pin; and
a motor coupled to the ball screw and, which rotates the ball screw.

12. The exposure apparatus of claim 6, wherein the plurality of support pins further include a second variable support pin configured to reciprocate in the second direction, and
wherein the plurality of holes further include third holes penetrated by the second variable support pin, extending in the first direction, and arranged in parallel along the second direction.

13. The exposure apparatus of claim 12, wherein opposite ends of each of the third hole are connected to the pair of first holes, respectively.

14. The exposure apparatus of claim 12, wherein a maximum value of a reciprocating movement range of the second variable support pin in the second direction is about 400 mm.

15. The exposure apparatus of claim 14, wherein a width of each of the third hole in the second direction is about 800 mm.

16. The exposure apparatus of claim 15, wherein the second holes include five or more second holes and the third holes include three or more third holes.

17. The exposure apparatus of claim 11, wherein the second holes are arranged in a matrix form having a plurality of rows extending in the first direction and a plurality of columns extending in the second direction.

18. A method of manufacturing a display device, the method comprising:
reciprocating a plurality of support pins in a first direction or in a second direction crossing the first direction;
loading a target substrate on a stage and supporting the target substrate with the plurality of support pins;
lowering the plurality of support pins;
radiating ultraviolet rays to the target substrate;
supporting the target substrate by lifting the plurality of support pins; and
unloading the target substrate from the stage.

19. The method of claim 18, wherein the target substrate includes an active area in which a plurality of cells are disposed and a non-active area surrounding the active area, and
wherein in the reciprocating of the plurality of support pins, positions of the plurality of support pins are adjusted so as to support the target substrate while being spaced apart from the active area and overlapping the non-active area in a plan view.

20. The method of claim 18, further comprising:
applying a monomer layer on the base substrate of the target substrate before the loading the target substrate.
